(19) United States
(12) Patent Application Publication
(10) Pub. No.: US 2022/0231635 A1
(43) Pub. Date: Jul. 21, 2022

(54) SYSTEMS AND METHODS FOR REMOVING DUST FROM SOLAR PANEL SURFACES USING AN ELECTRIC FIELD

(71) Applicant: Massachusetts Institute of Technology, Cambridge, MA (US)

(72) Inventors: Kripa Kiran Varanasi, Lexington, MA (US); Sreedath Panat, Cambridge, MA (US)

(21) Appl. No.: 17/614,868

(22) PCT Filed: Jun. 9, 2020
(86) PCT No.: PCT/US2020/036829

§ 371 Date: Nov. 29, 2021

Related U.S. Application Data
(60) Provisional application No. 62/859,654, filed on Jun. 10, 2019.

(51) Int. Cl. H02S 40/10; H01L 31/0236; B08B 6/00; F24S 40/20

(52) U.S. Cl. CPC H02S 40/10; F24S 40/20; B08B 6/00; H01L 31/02366

(57) ABSTRACT

Presented herein are systems and methods for waterless, contactless systems and methods for cleaning solar panels that can be applied, for example, to photovoltaics and solar reflector power plants. The systems and methods remove dust particles from surfaces using electrostatic induction.

### CROSS REFERENCE TO RELATED APPLICATIONS

This application claims priority to and benefit of U.S. Provisional Patent Application Ser. No. 62/859,654, filed on Jun. 10, 2019, entitled “Systems and Methods for Removing Dust from Solar Panel Surfaces using an Electric Field,” the disclosure of which is incorporated herein by reference in its entirety.

### TECHNICAL FIELD

This application relates to technologies for solar panels and use of the same.

### BACKGROUND

Solar power generally refers to the conversion of energy from sunlight into other form of power, for example, electricity. This conversion may be accomplished directly using photovoltaics (PV), i.e., conversion of sunlight directly into electricity using a semiconducting material that exhibit the photovoltaic effect. Alternatively, conversion may be accomplished indirectly using concentrated solar power. Concentrated solar power systems may use lenses or mirrors, or a combination thereof, and a solar tracking system to focus a large amount of sunlight into a small beam.

### SUMMARY

Presented herein are technologies for waterless, contactless systems and methods for cleaning solar panels that can be applied, for example, to photovoltaics and solar reflector power plants. The systems and methods described herein remove dust particles from surfaces using electrostatic induction. The technologies described may reduce or eliminate the use of water for solar panel cleaning in arid regions, and may reduce or eliminate scratching of solar panel surfaces caused by standard brushes.

Presented herein is a method for removing dust from a surface of a solar panel using an electric field. The method includes moving an electrode over a surface of an electrically conducting solar panel to apply a potential difference between the electrode and the surface of the solar panel. Thereby, a coulombic force for removing dust from the surface of the solar panel is provided. The solar panel surface includes a nanoscale texture layer and a thin transparent conductive oxide (TCO) film above the nanoscale texture layer.

Presented herein is a system for removing dust from a surface of a solar panel using an electric field. The system includes an electrode positioned over the surface of the solar panel. The system includes a solar panel with a surface including a nanoscale texture layer and a thin transparent conductive oxide (TCO) film above the nanoscale texture layer. The system includes a mechanism for moving the electrode over the surface of the solar panel to apply a potential difference between the electrode and the surface of the solar panel. Thereby a coulombic force for removing dust from the surface of the solar panel is provided.

Presented herein is a method for removing dust from a surface of a solar panel using an electric field. The method includes translating a first wire electrode over a surface of a solar panel adjacent to a second moving electrode. The second moving electrode is electrically grounded. Thereby dust particles on the surface of the solar panel are charged. The solar panel surface may include a nanoscale texture layer.

Presented herein is a system for performing the methods described herein. The system includes a solar panel with a surface including a nanoscale texture layer and a thin transparent conductive oxide (TCO) film above the nanoscale texture layer. The system includes an electrode positioned over the surface of the solar panel. The system includes a mechanism for moving the electrode over the surface of the solar panel to apply a potential difference between the electrode and the surface of the solar panel. Thereby, a coulombic force for removing dust from the surface of the solar panel is provided.

### BRIEF DESCRIPTION OF THE DRAWINGS

In the drawings, like reference characters generally refer to the same parts throughout the different views. Also, the drawings are not necessarily to scale, emphasis instead generally being placed upon illustrating the principles of the disclosed systems and methods and are not intended as limiting. For purposes of clarity, not every component may be labeled in every drawing. In the following description, various embodiments are described with reference to the following drawings.

FIG. 1 is a schematic representation of a parallel plate electrode setup for removal of dust from a surface, according to an illustrative embodiment.

FIG. 2A and FIG. 2B are photographs of a prototype electrostatic solar panel cleaning mechanism. FIG. 2A shows the prototype before cleaning. FIG. 2B shows the prototype after cleaning.

FIG. 3 is a graph illustrating power recovery after electrostatic dust repulsion from solar panels after applying an example technology described herein to an example surface fouled with dust particles of four different sizes.

FIG. 4 is a graph illustrating the effect of humidity of electrostatic dust removal from solar panels subjected to an example technologies described herein to an example surface fouled with dust particles of three different sizes

### DETAILED DESCRIPTION

Renewable energy systems have found tremendous growth in last decade. Among those, solar power systems including photovoltaics and solar power concentrators (reflectors) had nearly exponential growth increasing its global power production capacity from 9.2 GW in 2007 to 401 GW by the end of 2017. The global solar panel industry was estimated at $30.8 billion in 2016 and is projected to increase to $57.3 billion by 2022. Because the demand for solar power is increasing, there is significant focus on enhancing the operational efficiency of solar power systems. As a result, there is a large market for solar panel coatings, such as anti-reflective coatings that enhance the efficiency by up-to 30%. The global solar panel coatings market was estimated to be at $2 billion in 2017 and is estimated to reach $19 billion by 2026.

Solar power systems, however, virtually never operate at their full capacity due to various factors, but predominately, due to dust accumulation. To date, most of the large solar farms are located in dry regions such as deserts where land is cheap to acquire and sunlight is abundant. But these regions also have significant airborne and windborne dust that accumulate on top of the solar panels, reducing their light transmittance and, therefore, their power output. It has been shown that over a period of one month, the cumulative drop in power can be up to 25% if cleaning is not performed. For example, a 1% drop in efficiency in a 150 MW power plant amounts to $200,000 loss in annual revenue. Thus, solar panels should be cleaned regularly to minimize the losses.

The average Operation and Maintenance (O&M) cost of water-based cleaning systems for 1 MW solar panels is about $50,000 annually out of which 80% is the cleaning cost. A common method of cleaning solar panels today is cleaning with water or water-based solvents. Because large solar farms are frequently located in dry and sunlight abundant regions like deserts, water is at a premium. Even though the water-wash method is effective, cleaning acres of area of solar panels with water significantly adds to the global water footprint. Manual and robotic scrubbers are also common. Manual cleaning contributes to major labor expense. To cut the manual labor, several solar farms employ robotic cleaners that come with rotating brushes to scrub dust from the surface. Moreover, sand is an abrasive material, however, and scrubbing dust may have an effect similar to that of rubbing the smooth surface of solar panels with sandpaper. This process may cause irreversible scratching damage to the surface affecting long term operational efficiency of the panel.

Self-cleaning and/or water-less cleaning may bring down cleaning costs by a factor of 10-15 compared to water-based cleaning. Thus, self-cleaning solar panels according to illustrative embodiments described herein may provide a paradigm shift in the solar power industry. The described technologies for a waterless, contactless way of cleaning solar panels may be applied to photovoltaics as well as concentrated solar power plants.

Water-less cleaning methods may include electrostatic methods. Electrostatic methods include water-less methods that involve no mechanical rubbing and hence are very attractive for any application where mechanical contact with a surface is undesirable. These applications may include optical tools and devices, mirrors, lenses, fiber-optics, and the like. Mazumder et al. [7] have developed transparent conductive micro-electrodes that can be embedded into a panel surface. On applying alternating voltage across the electrodes, a traveling wave electric field is created that may be used to remove dust. In some embodiments, however, there may be a non-conducting transparent polyurethane film on top of the electrodes to prevent them from shorting due to moisture or water, for example, rain water. Hiroyuki Kawamoto [8] has developed mesh electrodes without any dielectric film. Moreover, TAFT Robotics from Taft instruments use moving electrode-based system to remove dust [6]. However, in all of these cases, dust particles are primarily removed not by charging, but by dielectrophoresis, which occurs due to the strong spatial gradient in the electric field strength. Dielectrophoretic force is generally a weak force in comparison to force experienced by charged particles in an electric field and hence is relevant only for larger sized particles, for example, particles of a diameter of more than 50 microns (μm). Thus, dielectrophoretic force has severe limitations when it comes to dust particles of size close to 10 microns, which constitutes a significant fraction of airborne dust [9]. For electrodes with dielectric film, porosity to moisture may constitute a problem: when such an electrode is exposed to the open air, moisture may seep-in and short-circuit the electrodes. In some cases, if the (dielectric) film is absent, then even dew drops may cause shorting. Hence the real-life application of these systems is limited to extremely low humidity environments, such as cleaning of solar panels on Mars rovers.

Presented herein are technologies for waterless, contactless systems and methods for cleaning solar panels that can be applied, for example, to photovoltaics and concentrated solar power plants. The systems and methods remove dust particles from surfaces using electrostatic induction.

Dust particles are composed primarily of silicon dioxide and several metallic oxides, but may include other types of particles. Other types of particles may have physical or electrochemical properties similar to those of silicon dioxide or other metallic oxides. In some implementations, oxides of certain metals present in dust, like iron and manganese, have electrical conductivity similar to that of semi-conductors. Also, under ambient conditions, adsorbed moisture may cause dust particles to behave like conductors. Thus, charge can be induced on dust particles by bringing them into contact with an electrode.

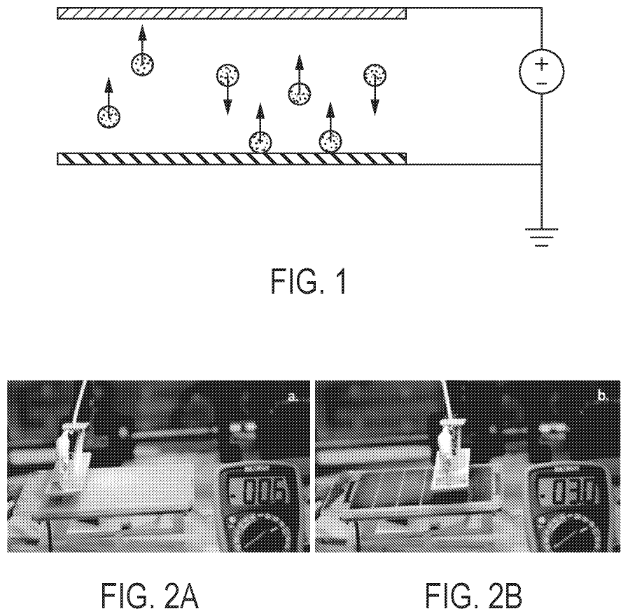

As shown in the schematic of FIG. 1, in a parallel-plate electrode setup, dust particles are observed to oscillate back and forth between the electrodes if the applied voltage is high enough to create an electrostatic force that can overcome gravitational force and the adhesion of dust to the electrode surface. Applying this concept, dust particles covering the top of a surface can be removed by letting the particles oscillate between the surface and a moving electrode that maintains a potential difference with the (electrically conducting surface). In some implementations, dust particles covering the top of a solar panel can be removed by letting the particles oscillate between the surface of the solar panel and a moving electrode that maintains a potential difference with the electrically conducting transparent solar panel surface. In certain embodiments, the solar panel surface may be made conductive by depositing a thin nanometric transparent conductive oxide (TCO) film, for example, a TCO film of zinc or tin that may be doped with doping substance, for example, aluminum or indium. In certain example embodiments, a solar panel surface may be made conductive by depositing a thin a TCO film of zinc doped with aluminum. In certain example embodiments, a solar panel surface may be made conductive by depositing a thin a TCO film of tin doped with indium. In some embodiments, the TCO film may include less than about 20%, about 10%, about 5%, about 3%, about 1%, about 0.5%, about 0.1% by weight of a doping substance, for example, aluminum or indium. In certain implementations, before depositing the TCO film, a nano-scale texture may be introduced on the panel surface to reduce van-der-Waals force of adhesion between dust particles and the solar panel surface, as well as to reduce reflection losses. In some implementations, the particles will oscillate and keep tracing the moving top electrode and eventually fall onto the ground.

FIG. 2 shows a lab-scale prototype of a solar-panel cleaning mechanism before and after removing dust from the solar panel surface, according to an illustrative embodiment.

The systems and methods described herein offer a significant improvement in the electrostatics-based self-cleaning solar panel industry. In certain embodiments, the systems and methods are based on contact charging, also known as electrostatic induction, which relies substantially (or completely) on coulombic force. Coulombic force is significantly stronger than dielectrophoretic force, especially for small particles. In certain embodiments, the systems and methods introduce nano-scale roughness on the panel surface that not only enhances light transmittivity, but also reduces the adhesion force of dust by one to two orders of magnitude. Coulombic force coupled with nano-scale roughness helps to effectively remove very small dust particles, for example, dust particles with a diameter of less than 10 microns. Because there are no inter-digitated electrodes on the panel surface, the problem of electrical shorting due to moisture is non-existent. Thus, embodiments described herein are not limited by humidity. Also, the technologies described herein may be significantly cheaper than existing technologies because it may be cheaper to coat a panel with a thin layer of nanoparticles and a transparent conductive coating of a few hundred molecules (for example, zinc oxide molecules) thickness as opposed to fabricating micro-electrodes and assembling them on top of a solar panel along with an insulating layer. A nano-textured surface as described herein may also be fabricated by pressing a (thin) transparent plastic film against a nano-textured metallic surface. This thin film may be coated with transparent conductive oxides (TCO) to have a transparent, flexible, nanotextured electrically conductive surface that can be retrofitted on top of solar panels. Moreover, the technologies may be easily scalable due to ease of manufacture of large transparently coated panels compared to panels with attached or incorporated micro-electrodes.

In some embodiments, dust particle charging is performed by space charge injection using a thin wire electrode that translates on top of solar panels adjacent to another moving electrode that is electrically grounded. In these embodiments, there is no need for making the solar panel surface conductive because charging occurs in a non-contact way. The thin wire electrode will cause ionization of air that results in charged dust particles that traces the motion of the moving wire.

Described herein are systems and methods for removing dust from a surface of a solar panel using an electric field. The method includes moving an electrode over a surface of an electrically conducting solar panel to apply a potential difference between the electrode and the surface of the solar panel, thereby providing a coulombic force for removing dust from the surface of the solar panel.

The electrode may be moved automatically, for example, using an electrode mounted on a moving arrangement. An example moving arrangement may include one or more moveable arm connected to a motor to move the one or more arms and/or the one or more electrodes in one or more directions. The motor may be controlled manually or by a computer control system. Movement of an electrode may occur in a sweeping motion, for example, in a linear or circular motion.

In certain embodiments, the electrode may be or may include a flat surface or a wire maintained sufficiently close to the surface of the solar panel throughout the movement, (for example, a sweep) of the electrode over the solar panel surface to provide the coulombic force for removing the dust. In some embodiments, the surface is rectangular, square, or circular. In some embodiments, the surface has a long edge and a short edge. An example sweeping motion may be or include a motion of the surface in a direction substantially perpendicular to the long edge. In some embodiments, the wire may be substantially straight along a length of the wire. An example sweeping motion may be or include a motion of the wire in a direction perpendicular to the length of wire.

In certain embodiments, providing the coulombic force causes dust particles to oscillate between the electrode and the solar panel surface and to fall off the solar panel. For example, dust particles may fall to the ground. In certain embodiments, providing the coulombic force causes dust particles to directly repel off from the solar panel and fall to the ground. In some embodiments, a system described herein may include needle-like sprayers that can spray electrically charged droplets of water to remove ultra-fine dust particles, for example, dust particles of less than 1 micron in size. In some embodiments, a system as described herein may include an aspiration system including a vacuum source and a conduit connected to the vacuum source (for example, attached to or mounted on the vacuum source). The conduit may include a first end connected to the vacuum source and a second end connected (for example, attached) to a vacuum head. In some implementations, the vacuum head is moveable together with the electrode. In some implementations, the vacuum head is stationary relative to the moveable electrode. In some embodiments, the vacuum head may be arranged or adapted such that the oscillating dust particles are sucked into the vacuum head once the coulombic force and the vacuum are applied.

In certain embodiments, the coulombic force charges the dust particles. In some embodiments, the dust particles include particles of 10 microns and/or below 10 microns in diameter. In some embodiments, the dust particles include particles of between 10 microns and 20 microns in diameter. In some embodiments, the dust particles include particles of between 20 microns and 30 microns in diameter. In some embodiments, the dust particles include particles of between 30 microns and 40 microns in diameter. In some embodiments, the dust particles include particles of between 40 microns and 50 microns in diameter. In some embodiments, the dust particles include particles of between 10 microns and 100 microns in diameter. In some embodiments, the dust particles include particles of between 100 microns and 500 microns in diameter. In some embodiments, the dust particles include particles of between 500 microns and 1000 microns in diameter.

A surface of a solar panel that may be used with the technologies described in this specification may include a nanoscale texture layer. In certain embodiments, the nanoscale texture layer may include nanoparticles (for example, nanospheres or nanorods) deposited on the solar panel. In certain embodiments, the nanoscale texture layer may include silica nanoparticles deposited on the solar panel. In some embodiments, the silica nanoparticles, may be or may include polydisperse or monodisperse particles. In some embodiments, the nanoparticles (for example, the silica nanoparticles) have an average diameter that falls within a range of from about 5 nm to about 1000 nm. In some embodiments, the nanoparticles (for example, the silica nanoparticles) have an average diameter that falls within a range of from about 10 nm to about 500 nm. In some embodiments, the nanoparticles (for example, the silica nanoparticles) have an average diameter that falls within a range of e.g., from about 100 nm to about 400 nm. In some embodiments, the nanoparticles, for example, the silica nanoparticles, may form a nanoscale texture layer. In some embodiments, the nanoscale texture layer has a thickness within a range from 5 nm to about 5000 nm. In some embodiments, the nanoscale texture layer has a thickness within a range from about 10 nm to about 1000 nm. In some embodiments, the nanoscale texture layer has a thickness within a range e.g., from about 100 nm to about 400 nm. In certain embodiments, the nanoscale texture layer enhances light transmittivity and/or reduces adhesion force of dust. In certain embodiments, the nanoscale texture layer may include a nanotextured transparent plastic film coated with transparent conductive oxide (TCO).

A surface of a solar panel that may be used with the technologies described in this specification may include a transparent conductive layer above the nanoscale texture layer. A surface of a solar panel that may be used with the technologies described in this specification may include a nanoscale texture layer and a transparent conductive film above the nanoscale texture layer. In some embodiments, a surface of a solar panel that may be used with the technologies described in this specification may include a nanoscale texture layer and a transparent conductive oxide (TCO) film layer above the nanoscale texture layer.

In certain embodiments, the solar panel is transparent. In certain embodiments, the solar panel is semi-transparent. In certain embodiments, the transparent conductive oxide (TCO) film may include an oxide of zinc. In certain embodiments, the TCO film may include an oxide of zinc doped with aluminum. In certain embodiments, the TCO film may include oxide of tin. In certain embodiments, the TCO film may include oxide of tin doped with indium In certain embodiments, TCO film may include an oxide of zinc and an oxide of tin. In certain embodiments, the TCO film may include an oxide of zinc and an oxide of tin with doping of aluminum or indium.

In certain embodiments, a transparent conductive oxide (TCO) film, for example, for use as a coating for a nanoscale texture layer or for use with a surface of a solar panel, has a thickness of less than 1000 atoms, for example, zinc atoms or tin atoms. In some embodiments, the transparent conductive oxide (TCO) film has a thickness of about 100 to about 600 atoms, for example, zinc atoms or tin atoms. In some embodiments, the transparent conductive oxide (TCO) film has a thickness of about 100 to about 500 atoms, for example, zinc atoms or tin atoms. In some embodiments, the transparent conductive oxide (TCO) film has a thickness of about 100 to about 400 atoms, for example, zinc atoms or tin atoms. In some embodiments, the transparent conductive oxide (TCO) film has a thickness of about 100 to about 300 atoms, for example, zinc atoms or tin atoms.

In certain embodiments, the thin transparent conductive oxide (TCO) film is positioned directly upon the nanoscale texture layer with no other layers in between. In certain embodiments, the thin transparent conductive oxide (TCO) film is positioned upon the nanoscale texture layer with one or more other layers in between.

In certain embodiments, the nanoscale texture layer includes a random nanotexture. As such, in certain embodiments, the nanoscale texture layer may include a surface and a random arrangement of nano-scale structures. In certain embodiments, the nanoscale texture layer includes an ordered or semi-ordered nanotexture. As such, in certain embodiments, the nanoscale texture layer may include a surface and an ordered or semi-random arrangement of nano-scale structures. In some embodiments, the nanotexture may include grooves, ridges, pits, divots, hemispheres, cones, columns, fibers, or similar. In some embodiments, the nanotexture may include grooves, lines, pits, divots, or similar, of a height or depth of less than 1000 nanometers. In some embodiments, the nanotexture may include grooves, ridges, pits, divots, hemispheres, cones, columns, fibers, or similar, of an average height or depth (as applicable) compared to the surface of less than 900 nanometers, less than 800, less than 700 nanometers, less than 600 nanometers, less than 500, less than 400 nanometers, less than 300 nanometers, less than 200, less than 100 nanometers, less than 50 nanometers, less than 40 nanometers, less than 30 nanometers, less than 20 nanometers, less than 10 nanometers, less than 5 nanometers, or less than 1 nanometer.

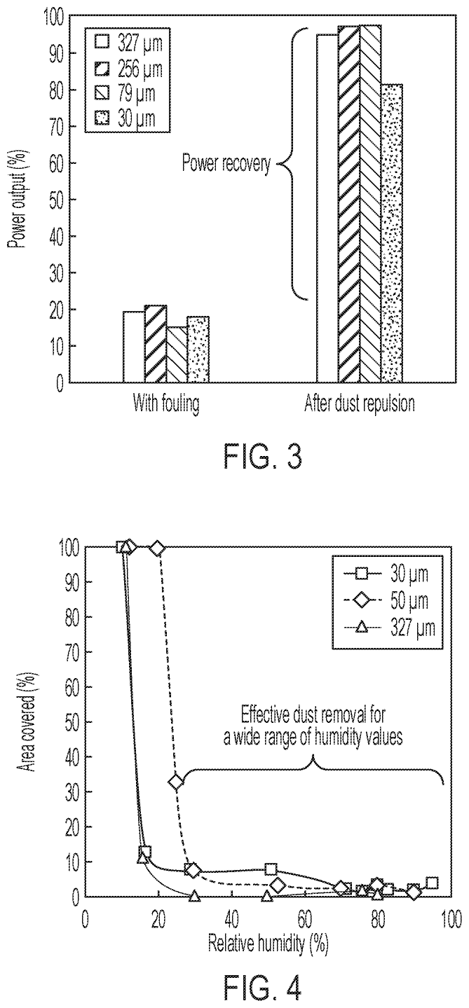

The technologies described herein may significantly improve power output of a cleaned solar panel compared to a fouled surface. A dust repulsion experiment applying dust particles of several sizes (30-327 microns (μm)) was carried out. FIG. 3 shows the power output from a laboratory-scale solar panel before and after removing dust by electrostatic repulsion for the select dust particle sizes. The solar panel used in this example was a laboratory scale model with about 2 Watts power output. Dimensions were approximately 10 cm×15 cm. The surface coating used was made of aluminum doped with zinc oxide and had a thickness of about 5 nanometers (nm). The surface in this example did not have a nanotexture. The voltage applied was about 10 kV. The space between the moving (ground) electrode and the surface (acting as second electrode) was about 2 cm. In this experiment, the electrodes were swept over the surface. The speed of motion of the moving electrodes was around 1 cm/s. It was found that up-to 95% of lost power can be recovered through the dust removal process described herein.

The effect of relative humidity of ambient air on the dust removal technologies described herein were evaluated. The experimental setup was similar to that described above regarding the power recovery with the following exception: this particular experiment was performed on a surface of a smooth silicon wafer instead of solar panel surface. The results, however, are applicable to solar panel surfaces coated with transparent conductive oxides (TCO). Dust particles may adsorb moisture and obtain charge from the surface if the relative humidity is moderately high (for example, greater than about 30%). The effect of fluctuation in ambient humidity was tested using a humidity-controlled acrylic chamber. Humidity was controlled by using nitrogen purging to reduce humidity and a humidifier to increase the humidity. FIG. 4 shows the efficacy of dust removal for different relative humidity values. The percentage area of the surface covered with dust particles after electrostatic dust repulsion is plotted on the Y-axis. It can be seen that for a wide range of relative humidity values from 20% to 95%, the electrostatic dust repulsion is highly effective, leaving only few particles on the surface. For extremely low humidity values (for example, relative humidity of less than 30%), dust particles tended to remain on the surface. This effect may be due to lack of enough moisture to cause charge transfer. Low humidity, however, may not pose any issues in electrostatic dust removal in a desert environment. Most deserts experience fluctuation in humidity throughout the day. Humidity may be relatively high (for example, in the morning) such that dew may form on surfaces [15]. Thus, dust particles can be charged and repelled from solar panels when a dust removal mechanism as described herein is operated during the time of the day when humidity is comparatively high, for example, higher than 30%. A system as described herein may not experience electrical shorting or breakdown even at extremely high relative humidity of greater than 90% unlike conventional electrostatic dust removal systems. In the described system, there is a gap of about 2 cm between the bottom (transparent) electrode and moving ground electrode. Moisture cannot cause electrical shorting at such large gaps unless the electric field strength is extremely high to cause breakdown of air. In conventional electrostatic solar panel cleaners, the gap between electrodes embedded in a panel is less than 1 millimeter. These conventional systems are prone to breakdown because moisture (droplets) may penetrate these gaps and accumulate, causing electrical shorting.

Described herein is a system for removing dust from a surface of a solar panel using an electric field, for example for performing any of the methods described herein. The system includes an electrode positioned over the surface of the solar panel and a solar panel with a surface including a nanoscale texture layer and a thin transparent conductive oxide (TCO) film above the nanoscale texture layer. The system includes a mechanism for moving the electrode over the surface of the solar panel to apply a potential difference between the electrode and the surface of the solar panel, thereby providing a coulombic force for removing dust from the surface of the solar panel. The mechanism may be for automatically moving the electrode, for example, in a sweeping motion.

Described herein is a method for removing dust from a surface of a solar panel using an electric field. The method includes translating a first wire electrode over a surface of a solar panel adjacent to a second moving electrode. The second moving electrode is electrically grounded, thereby charging dust particles on the surface of the solar panel, for example, via space charge injection. The solar panel surface may include a nanoscale texture layer. In some embodiments, there may be no need to make the solar panel surface conductive because charging occurs in a non-contact way.

At least part of the technologies described herein and their modifications may be controlled, at least in part, by a computer program product, such as a computer program tangibly embodied in one or more information carriers, such as in one or more tangible machine-readable storage media, for execution by, or to control the operation of, data processing apparatus, for example, a programmable processor, a computer, or multiple computers, as would be familiar to one of ordinary skill in the art.

It is contemplated that systems, devices, methods, and processes of the present application encompass variations and adaptations developed using information from the embodiments described in the following description. Adaptation or modification of the methods and processes described in this specification may be performed by those of ordinary skill in the relevant art.

Throughout the description, where compositions, compounds, or products are described as having, including, or comprising specific components, or where processes and methods are described as having, including, or comprising specific steps, it is contemplated that, additionally, there are articles, devices, and systems of the present application that consist essentially of, or consist of, the recited components, and that there are processes and methods according to the present application that consist essentially of, or consist of, the recited processing steps.

It should be understood that the order of steps or order for performing certain actions is immaterial, so long as the described method remains operable. Moreover, two or more steps or actions may be conducted simultaneously.

### Embodiments

Embodiment 1: A method for removing dust from a surface of a solar panel using an electric field, the method including: moving an electrode over a surface of an electrically conducting solar panel to apply a potential difference between the electrode and the surface of the solar panel, thereby providing a coulombic force for removing dust from the surface of the solar panel, wherein the solar panel surface includes a nanoscale texture layer and a thin transparent conductive oxide (TCO) film above the nanoscale texture layer.

Embodiment 2: The method of Embodiment 1, wherein moving the electrode occurs in a sweeping motion.

Embodiment 3: The method of Embodiment 1 or Embodiment 2, wherein the electrode is a flat surface or a wire maintained sufficiently close to the surface of the solar panel throughout the movement of the electrode over the solar panel surface to provide the coulombic force for removing the dust.

Embodiment 4: The method of any one of Embodiments 1 to 3, wherein providing the coulombic force causes dust particles to oscillate between the electrode and the solar panel surface and to fall off the solar panel.

Embodiment 5: The method of any one of Embodiments 1 to 4, wherein providing the coulombic force charges the dust particles.

Embodiment 6: The method of any one of Embodiments 1 to 5, wherein the dust particles includes particles of a diameter of between 10 and 500 microns or a diameter of 10 microns or less.

Embodiment 7: The method of any one of Embodiments 1 to 6, wherein the nanoscale texture layer includes silica nanoparticles deposited on the solar panel.

Embodiment 8: The method of any one of Embodiments 1 to 7, wherein the silica nanoparticles have a diameter of between about 100 nm and about 400 nm.

Embodiment 9: The method of any one of Embodiments 1 to 8, wherein the nanoscale texture layer has a thickness of between about 100 nm and about 400 nm.

Embodiment 10: The method of any one of Embodiments 1 to 9, wherein the nanoscale texture layer enhances light transmittivity and/or reduces adhesion force of dust.

Embodiment 11: The method of any one of Embodiments 1 to 10, wherein the solar panel is transparent.

Embodiment 12: The method of any one of Embodiments 1 to 11, wherein the transparent conductive oxide (TCO) film includes an oxide of zinc with aluminum doping and/or an oxide of tin with indium doping.

Embodiment 13: The method of any one of Embodiments 1 to 12, wherein the transparent conductive oxide (TCO) film has a thickness of less than 1000 zinc oxide molecules.

Embodiment 14: The method of any one of Embodiments 1 to 13, wherein the transparent conductive oxide (TCO) film has a thickness of about 100 to about 600 zinc oxide molecules.

Embodiment 15: The method of any one of Embodiments 1 to 14, wherein the thin transparent conductive oxide (TCO) film is positioned directly upon the nanoscale texture layer with no other layers in between.

Embodiment 16: The method of any one of Embodiments 1 to 15, wherein the thin transparent conductive oxide (TCO) film is positioned upon the nanoscale texture layer with one or more other layers in between.

Embodiment 17: The method of any one of Embodiments 1 to 16, wherein the nanoscale texture layer includes a random nanotexture.

Embodiment 18: A system for removing dust from a surface of a solar panel using an electric field, the system including: an electrode positioned over the surface of the solar panel; a solar panel with a surface including a nanoscale texture layer and a thin transparent conductive oxide (TCO) film above the nanoscale texture layer; and a mechanism for moving the electrode over the surface of the solar panel to apply a potential difference between the electrode and the surface of the solar panel, thereby providing a coulombic force for removing dust from the surface of the solar panel.

Embodiment 19: The system of Embodiment 18, wherein the moving includes automatic moving.

Embodiment 20: The system of Embodiment 18 or Embodiment 19, wherein the moving includes moving in a sweeping motion.

Embodiment 21: A method for removing dust from a surface of a solar panel using an electric field, the method including: translating a first wire electrode over a surface of a solar panel adjacent to a second moving electrode, the second moving electrode being electrically grounded, thereby charging dust particles on the surface of the solar panel,

Embodiment 22: The method of Embodiment 21, wherein the solar panel surface optionally includes a nanoscale texture layer.

Embodiment 23: The method of Embodiment 21 or Embodiment 22, wherein charging dust particles on the surface of the solar panel includes via space charge injection.

Embodiment 23: A system for performing the method of any one of Embodiments 1 to 16 and 21 to 23, the system including: a solar panel with a surface including a nanoscale texture layer and a thin transparent conductive oxide (TCO) film above the nanoscale texture layer; an electrode positioned over the surface of the solar panel, and a mechanism for moving the electrode over the surface of the solar panel to apply a potential difference between the electrode and the surface of the solar panel, thereby providing a coulombic force for removing dust from the surface of the solar panel.

### REFERENCES

The following documents are incorporated herein by reference in their entireties:
1. IEA report (2016), Snapshot of global photovoltaic markets.
2. Zorilla-Casanova et al., Analysis of dust losses in photovoltaic modules, World renewable energy congress-2011, Sweden.
3. Cohen, Kearney, Kolb, Sandia Lab Report on CSP SAND99-1290.
4. Rudolf Husar (2004), Intercontinental Transport of Dust: Historical and Recent Observational Evidence, The Handbook of Environmental Chemistry Vol 4.
5. Zhang, Y. et al. (2015), Electric field and humidity trigger contact electrification, Physical Review X.
6. Nicoletta Ferretti, PV Module Cleaning—Market Overview and Basics, PI Berlin.
7. Mazumder, M. et al. (2013), Characterization of electrodynamic screen performance for dust removal from solar panels and solar hydrogen generators, IEEE Transactions on Industry Applications.
8. Hiroyuki Kawamoto (2019), Electrostatic cleaning equipment for dust removal from soiled solar panels, Journal of Electrostatics.
9. Mahowald et al. (2014), The size distribution of desert dust aerosols and its impact on the Earth system, Aeolian research.
10. Das, S. et al., Silica nanoparticles on front glass for efficiency enhancement in superstrate-type amorphous silicon solar cells, J. Phys. D: Appl. Phys. (2013)
11. Rabinovich et al. (2000), Adhesion between nanoscale surface roughness, Journal of Colloid and Interface Science.
12. Solar Panel Market (Mono-crystalline, Poly-crystalline, and Thin-film Solar Panel) for Residential, Commercial and Utility Applications: Global Industry Perspective, Comprehensive Analysis and Forecast, 2016-2022, Zion market research.
13. Solar Panel Coatings Market (Type—Anti-reflective, Hydrophobic, Self-cleaning, Anti-soiling, Anti-abrasion; End use Industry—Residential, Commercial, Energy, Agriculture, Automotive)—Global Industry Analysis, Size, Share, Growth, Trends, and Forecast 2017-2026, Transparency market research, 2018.
14. India's Very Own Waterless Solar Panel Cleaning Robot, www.cleanfuture.co.in, 2018.
15. Ilse, K. K., Figgis, B. W., Naumann, V., Hagendorf, C. & Bagdahn, J. Fundamentals of soiling processes on photovoltaic modules. Renew. Sustain. Energy Rev. 98, 239-254 (2018).

While the invention has been particularly shown and described with reference to specific preferred embodiments, it should be understood by those skilled in the art that various changes in form and detail may be made therein without departing from the spirit and scope of various embodiments of the invention as defined by the appended claims.

What is claimed is:

1. A method for removing dust from a surface of a solar panel using an electric field, the method comprising:
moving an electrode over a surface of an electrically conducting solar panel to apply a potential difference between the electrode and the surface of the solar panel, thereby providing a coulombic force for removing dust from the surface of the solar panel, wherein the solar panel surface comprises a nanoscale texture layer and a thin transparent conductive oxide (TCO) film above the nanoscale texture layer.

2. The method of claim 1, wherein moving the electrode occurs in a sweeping motion.

3. The method of claim 1, wherein the electrode is a flat surface or a wire maintained sufficiently close to the surface of the solar panel throughout the movement of the electrode over the solar panel surface to provide the coulombic force for removing the dust.

4. The method of claim 1, wherein providing the coulombic force causes dust particles to oscillate between the electrode and the solar panel surface and to fall off the solar panel.

5. The method of claim 4, wherein providing the coulombic force charges the dust particles.

6. The method of claim 4, wherein the dust particles comprise particles of a diameter of between 10 and 500 microns or a diameter of 10 microns or less.

7. The method of claim 1, wherein the nanoscale texture layer comprises silica nanoparticles deposited on the solar panel.

8. The method of claim 7, wherein the silica nanoparticles have a diameter of between about 100 nm and about 400 nm.

9. The method of claim 7, wherein the nanoscale texture layer has a thickness of between about 100 nm and about 400 nm.

10. The method of claim 1, wherein the nanoscale texture layer enhances light transmittivity and/or reduces adhesion force of dust.

11. The method of claim 1, wherein the solar panel is transparent.

12. The method of claim 1, wherein the transparent conductive oxide (TCO) film comprises an oxide of zinc with aluminum doping and/or an oxide of tin with indium doping.

13. The method of claim 1, wherein the transparent conductive oxide (TCO) film has a thickness of less than 1000 zinc oxide molecules.

14. The method of claim 1, wherein the transparent conductive oxide (TCO) film has a thickness of about 100 to about 600 zinc oxide molecules.

15. The method of claim 1, wherein the thin transparent conductive oxide (TCO) film is positioned directly upon the nanoscale texture layer with no other layers in between.

16. The method of claim 1, wherein the thin transparent conductive oxide (TCO) film is positioned upon the nanoscale texture layer with one or more other layers in between.

17. The method of claim 1, wherein the nanoscale texture layer comprises a random nanotexture.

18. A system for removing dust from a surface of a solar panel using an electric field, the system comprising:
an electrode positioned over the surface of the solar panel;
a solar panel with a surface comprising a nanoscale texture layer and a thin transparent conductive oxide (TCO) film above the nanoscale texture layer; and
a mechanism for moving the electrode over the surface of the solar panel to apply a potential difference between the electrode and the surface of the solar panel, thereby providing a coulombic force for removing dust from the surface of the solar panel.

19. The system of claim 18, wherein the moving comprises automatic moving.

20. The system of claim 18, wherein the moving comprises moving in a sweeping motion.

21. A method for removing dust from a surface of a solar panel using an electric field, the method comprising:
translating a first wire electrode over a surface of a solar panel adjacent to a second moving electrode, the second moving electrode being electrically grounded, thereby charging dust particles on the surface of the solar panel.

22. The method of claim 21, wherein the solar panel surface comprises a nanoscale texture layer.
